(19) United States
(12) Patent Application Publication
(10) Pub. No.: US 2024/0268084 A1
(43) Pub. Date: Aug. 8, 2024

(54) CONTAINERIZED DATA CENTER AND REFRIGERATION METHOD THEREOF

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/420,964

(22) Filed: Jan. 24, 2024

(30) Foreign Application Priority Data
Feb. 6, 2023 (CN) 202310080970.6

(51) Int. Cl. H05K 7/20

(52) U.S. Cl. CPC H05K 7/20827; H05K 7/20836

(57) ABSTRACT

The present disclosure discloses a containerized data center and a refrigeration method thereof. The containerized data center at least includes a container body and an integrated refrigeration apparatus. The container body is internally provided with a to-be-cooled device set dividing internal space of the container body into a cold channel and a hot channel. The integrated refrigeration apparatus at least includes a body, and a liquid cooling system and an air cooling system installed in the body. The body has an outdoor air inlet, an outdoor air outlet, an operating air inlet and an operating air outlet. The operating air inlet is interconnected to the hot channel, and the operating air outlet is interconnected to the cold channel. The liquid cooling system at least includes a dry cooler and a liquid supply and return pipe connected in series with the dry cooler.

### CROSS REFERENCE TO RELATED APPLICATION

This application claims priority to Chinese patent application Ser. No. 202310080970.6, titled “CONTAINERIZED DATA CENTER AND REFRIGERATION METHOD THEREOF” and filed to the China National Intellectual Property Administration on Feb. 6, 2023, the entire contents of which are incorporated herein by reference.

### TECHNICAL FIELD

The present disclosure relates to the field of server devices, and more particularly, to a containerized data center and a refrigeration method thereof.

### BACKGROUND

As heat dissipation of GPU/CPU continues to increase, power consumption for refrigeration of data centers increases, and power usage effectiveness (PUE) of the data centers continues to increase. In this case, a liquid cooling cold plate refrigeration solution is widely used as a mainstream solution in the data center industry. However, in the liquid cooling cold plate refrigeration solution, only part of cold energy can be taken away, while remaining part of the cold energy needs to be taken away by a separate cold source. Therefore, two sets of cold source systems need to be designed.

However, the existing two sets of cold source systems are installed separately, which requires larger space occupation. In addition, the two systems are relatively complex in layout, and internal pipelines are tangled and disorderly, making the existing two sets of cold source systems unsuitable for containerized data centers with narrow space.

### SUMMARY

Objectives of the present disclosure are to provide a containerized data center and a refrigeration method thereof, which can solve a problem that two cooling systems occupy a larger volume, making it convenient to arrange the two cooling systems in the containerized data center.

To achieve the above objectives, in one aspect the present disclosure provides a containerized data center, which at least includes a container body and an integrated refrigeration apparatus. The container body is internally provided with a to-be-cooled device set dividing internal space of the container body into a cold channel and a hot channel. The integrated refrigeration apparatus at least includes a body, and a liquid cooling system and an air cooling system, where the body is connected to one end of the container body, and the liquid cooling system and the air cooling system are installed in the body. The body has an outdoor air inlet, an outdoor air outlet, an operating air inlet, and an operating air outlet. The operating air inlet is interconnected to the hot channel, and the operating air outlet is interconnected to the cold channel, such that after heat exchange through the air cooling system, hot air in the hot channel is discharged into the cold channel through the operating air outlet. The liquid cooling system at least includes a dry cooler and a liquid supply and return pipe connected in series with the dry cooler, where the dry cooler is positioned between the outdoor air inlet and the outdoor air outlet. A plurality of liquid cooling cold plates are connected in series with the liquid supply and return pipe, the plurality of liquid cooling cold plates are connected in parallel with each other, and the plurality of liquid cooling cold plates respectively come into contact with a heat source of the to-be-cooled device set.

To achieve the above objectives, in another aspect the present disclosure also provides a refrigeration method for a containerized data center. The refrigeration method is applied to the containerized data center, which is provided with a liquid cooling system and an air cooling system. The refrigeration includes: starting the liquid cooling system and obtaining outdoor temperature; determining magnitude of the outdoor temperature, of a first temperature, of a second temperature and of a third temperature, where the first temperature is less than the second temperature; turning off a fluorine pump and a compressor in the air cooling system when the outdoor temperature is lower than the first temperature; turning on the fluorine pump and turning off the compressor when the outdoor temperature is higher than the first temperature and is lower than the second temperature; and turning on the compressor and turning off the fluorine pump when the outdoor temperature is higher than the second temperature.

As can be seen from the technical solutions provided in the present disclosure, an integrated refrigeration apparatus is connected to one side of the container body. The integrated refrigeration apparatus includes a body, a liquid cooling system, and an air cooling system. Both the liquid cooling system and the air cooling system are installed in the container body. That is, the two cooling systems are integrated into one body. Moreover, the liquid cooling system and the air cooling system share the same outdoor air inlet and the same outdoor air outlet, such that structures of the refrigeration apparatus can be further simplified, manufacturing costs can be lowered, and volumes occupied by the two cooling systems can be reduced. Thus, the two cooling systems are suitable to be arranged in the containerized data center.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic vertical view of a containerized data center according to an embodiment of the present disclosure;

FIG. 2 is an A-A sectional view of FIG. 1;

FIG. 3 is a schematic front view of an integrated refrigeration apparatus according to an embodiment of the present disclosure;

FIG. 4 is a schematic vertical view of the integrated refrigeration apparatus according to an embodiment of the present disclosure; and

FIG. 5 is a schematic workflow diagram of a refrigeration cycle according to an embodiment of the present disclosure.

### DETAILED DESCRIPTION

Detailed description of the embodiments of the present disclosure will further be made below with reference to drawings to make the above objectives, technical solutions and advantages of the present disclosure more apparent. Terms such as “upper” , “above” , “lower” , “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

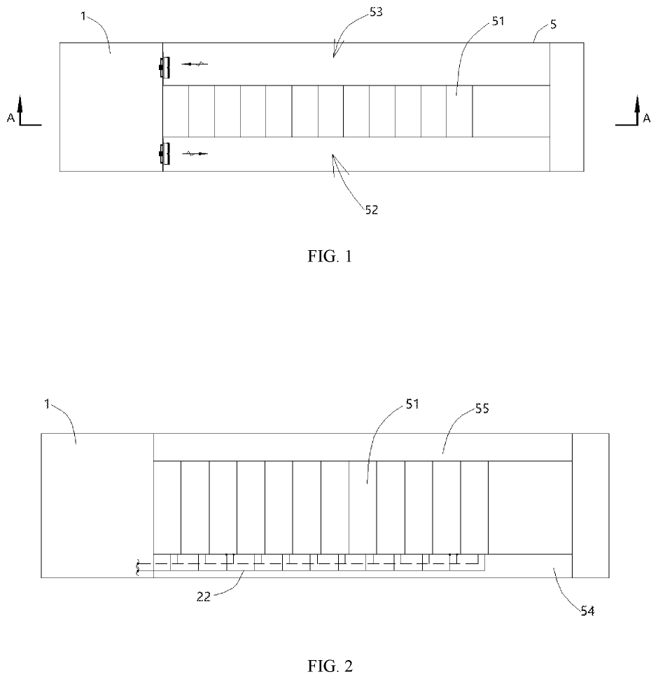

Referring to FIGS. 1 to 4 together, in an implementable embodiment, a containerized data center may at least include a container body 5 and an integrated refrigeration apparatus 1. The container body 5 is internally provided with a to-be-cooled device set 51, which divides internal space of the container body 5 into a cold channel 52 and a hot channel 53. It should be pointed out that the to-be-cooled device set 51 may be a cabinet provided with a server, a power distribution cabinet, a monitoring cabinet, and battery cell, etc. These components are arranged in a linear array, and two ends of the to-be-cooled device set 51 are respectively connected to two ends of the internal space of the container body 5, thereby dividing the internal space of the container body 5 into the cold channel 52 and the hot channel 53.

In one embodiment, the integrated refrigeration apparatus 1 at least includes a body 10, a liquid cooling system and an air cooling system, where the body 10 is connected to one end of the container body 5. Both the liquid cooling system and the air cooling system are installed in the body 10. The liquid cooling system and the air cooling system are both configured to cool the to-be-cooled device set 51 inside the container body 5. The body 10 has an outdoor air inlet 11, an outdoor air outlet 12, an operating air inlet 13, and an operating air outlet 14. The operating air inlet 13 is interconnected to the hot channel 53, and the operating air outlet 14 is interconnected to the cold channel 52. In this way, hot air in the hot channel 53 may enter the body 10 through the operating air inlet 13. After heat exchange through the air cooling system, the hot air cooled is discharged into the cold channel 52 through the operating air outlet 14, thereby achieving internal refrigeration cycle of air in the container body 5. The liquid cooling system may at least include a dry cooler 21 and a liquid supply and return pipe 22 connected in series with the dry cooler 21, where the dry cooler 21 is positioned between the outdoor air inlet 11 and the outdoor air outlet 12. A plurality of liquid cooling cold plates are connected in series with the liquid supply and return pipe 22, the plurality of liquid cooling cold plates are connected in parallel with each other, and the plurality of liquid cooling cold plates respectively come into contact with a heat source (such as CPU and GPU) of the to-be-cooled device set 51. Reference may be made to the existing technologies for specific structures of the dry cooler 21 and the liquid cooling cold plates, which are not to be described in detail here.

In this embodiment, the two cooling systems are integrated into one body 10. Moreover, the liquid cooling system and the air cooling system share the same outdoor air inlet 13 and the same outdoor air outlet 14 to carry out heat exchange with external air, such that structures of the refrigeration apparatus can be simplified, manufacturing costs can be lowered, and volumes occupied by the two cooling systems can be reduced. Thus, the two cooling systems are suitable to be arranged in the containerized data center.

It is to be particularly pointed out that the body 10 and the container body 5 in the present disclosure may be of an integrated structure. For example, one container is partitioned into two spaces by a spacer plate, where one space serves as the body 10, and the other one serves as the container body 5. Of course, the body 10 and the container body 5 may also be standalone structures. For example, the container body 5 is an additional container body attached to an outer side of the body 10.

In an implementable embodiment, as shown in FIG. 2, the to-be-cooled device set 51 may be installed in the container body 5 through an overhead seat 54. The liquid supply and return pipe 22 between the liquid cooling cold plate and the dry cooler 21 may be arranged in the overhead seat 54. In this way, it is avoidable that pipelines are exposed outside, thereby avoiding adversely affecting daily maintenance and operation, and ensuring aesthetic degree of the containerized data center.

In practical applications, the liquid cooling system comprised of the liquid cooling cold plate, the dry cooler 21 and the liquid supply and return pipe 22 should also have a pump body for driving circulation of refrigerating mediums in the liquid cooling system. A top of the to-be-cooled device set 51 may be provided with a cable tray 55, which is used for installation of a power distribution line. As can be seen, the power distribution line and the liquid supply and return pipe 22 are respectively arranged at top and at bottom to form physical isolation, thereby reducing failure propagation and avoiding mutual influence.

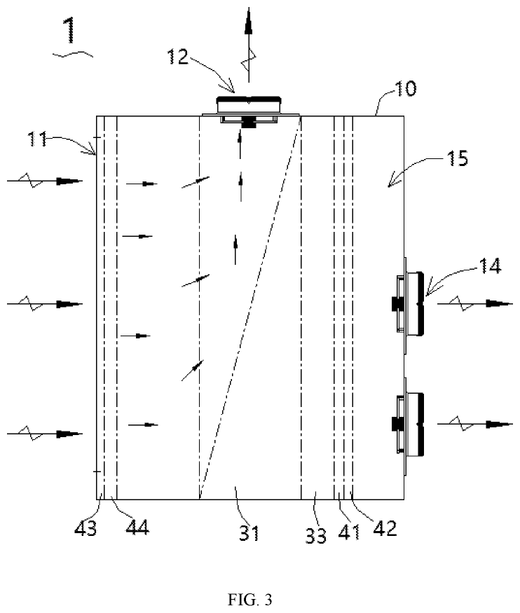

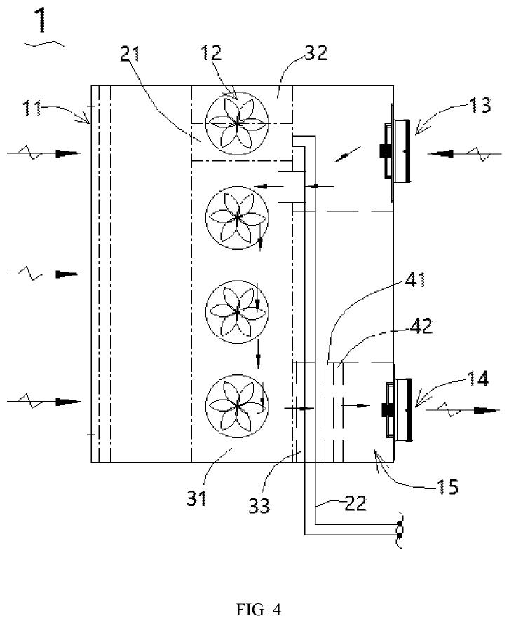

In an implementable embodiment, as shown in FIG. 3 and FIG. 4, the air cooling system at least includes a heat exchange core 31. An internal circulation air inlet of the heat exchange core 31 is interconnected to the operating air inlet 13, and an internal circulation air outlet of the heat exchange core 31 is interconnected to the operating air outlet 14. That is, the external air entering from the operating air inlet 13 and discharged through the operating air outlet 14 may flow through the heat exchange core 31, thereby exchanging heat with internal circulation air entering from the operating air inlet 13 and discharged through the operating air outlet 14, to achieve heat exchange with the internal circulation air.

In practical applications, the operating air inlet 13 and the operating air outlet 14 are respectively interconnected to the space where the to-be-cooled device set 51 is positioned. The liquid cooling cold plate interconnected to the liquid supply and return pipe 22 may be attached to a heat source of the to-be-cooled device set 51. The external air entering from the operating air inlet 13 and discharged through the operating air outlet 14 may simultaneously exchange heat with the heat exchange core 31 and the dry cooler 21. In this way, the liquid cooling system and the air cooling system may simultaneously refrigerate the space where the to-be-cooled device set 51 is positioned and the heat source. Moreover, the dry cooler 21 and the heat exchange core 31 may share one external air heat exchange channel, which can further simplify the structure of the refrigeration apparatus, and can reduce the manufacturing costs and manufacturing complexity.

It is to be pointed out that reference may be made to the existing technologies for specific structures of the heat exchange core 31, which are not to be described in detail here.

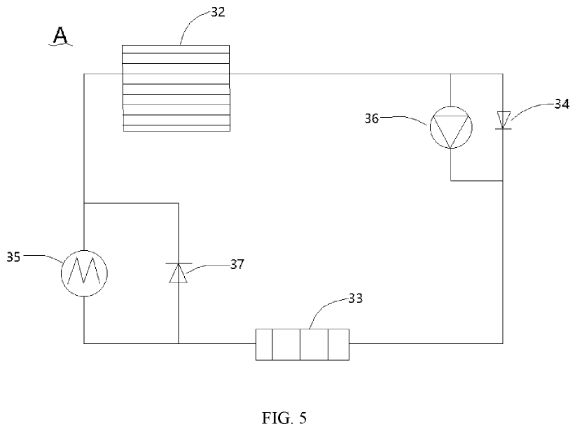

In an implementable embodiment, as shown in FIG. 4 and FIG. 5, air outlet channel 15 is connected between the internal circulation air outlet and the operating air outlet 14. The air cooling system also includes a condenser 32, an evaporator 33, an expansion valve 34, and a compressor 35. The condenser 32, the evaporator 33, the expansion valve 34 and the compressor 35 are connected in series with each other to form a refrigeration cycle A. The condenser 32 is positioned between the outdoor air inlet 11 and the outdoor air outlet 12, and the evaporator 33 is installed in the air outlet channel 15.

In this embodiment, the internal circulation air not only can exchange heat with the external air through the heat exchange core, but also can carry out secondary heat exchange through the evaporator in refrigeration cycle A to meet different heat dissipation needs.

The above air cooling system may also include a fluorine pump 36 and a one-way valve 37. The fluorine pump 36 is connected in series in the refrigeration cycle A, and the fluorine pump 36 is connected in parallel with the expansion valve 34. The one-way valve 37 is connected in series in the refrigeration cycle A, and the one-way valve 37 is connected in parallel with the compressor 35. In this way, the fluorine pump 36 or the compressor 35 may be selectively started according to actual usage requirements, thereby further expanding applicable usage environment and reducing energy consumption.

Further, the heat exchange core 31, the dry cooler 21, and the condenser 32 should be arranged side by side. In this way, when entering the body 10 through the outdoor air inlet, the external air may evenly blow through the heat exchange core 31, the dry cooler 21 and the condenser 32, thereby exchanging heat and preventing the heat exchange core 31, the dry cooler 21 and the condenser 32 from mutually overlapping, and thus avoiding adversely affecting heat exchange effects.

In an implementable embodiment, a humidification and dehumidification section 41 is installed in the air outlet channel 15, and the humidification and dehumidification section 41 is positioned between the operating air outlet 14 and the evaporator 33. In this way, after temperature and humidity requirements are met, the internal circulation air is delivered into the space where the to-be-cooled device set 51 is positioned.

It is to be pointed out that the humidification and dehumidification section 41 is one of functional sections of a combined air handling unit. Due to seasonal changes, when air humidity is required to be reduced or increased, air dehumidification or humidification treatment is carried out. Reference may be made to the existing technologies for the specific structure of the humidification and dehumidification section 41, which is not to be described in detail here.

Further, a filter section 42 may also be installed in the air outlet channel 15 to filter airflow flowing through the air outlet channel 15, thereby ensuring cleanliness of the internal circulation air entering the space where the to-be-cooled device set 51 is positioned.

In practical applications, the filter section 42 may be an initial, medium or sub-high efficiency filter section or a chemical filter section.

Further, a rainproof shutter 43 and a filter mesh 44 are installed at the outdoor air inlet 11 to prevent rainwater and debris from entering from the outdoor air inlet 11.

In one embodiment, the operating air inlet 13 and the operating air outlet 14 are positioned on the same side of the body 10, thereby facilitating interconnection with the space where the to-be-cooled device set 51 is positioned. The outdoor air inlet 11, the outdoor air outlet 12, and the operating air inlet 13 are respectively positioned on different side faces of the body 10. In one aspect, this facilitates device installation and operation, and in another aspect, this can prevent the external air from mixing with each other, thus avoiding adversely affecting heat dissipation effects of the dry cooler 21, of the heat exchange core 31, and of the condenser 32.

Based on the same inventive concept, the present disclosure also provides a refrigeration method for a containerized data center. The refrigeration method is applied to the containerized data center, which is provided with a liquid cooling system and an air cooling system. The method includes:

starting the liquid cooling system and obtaining outdoor temperature;

determining magnitude of the outdoor temperature, of a first temperature, of a second temperature and of a third temperature, where the first temperature is less than the second temperature;

turning off a fluorine pump 36 and a compressor 35 in the air cooling system when the outdoor temperature is lower than the first temperature;

turning on the fluorine pump 36 and turning off the compressor 35 when the outdoor temperature is higher than the first temperature and is lower than the second temperature; and

turning on the compressor 35 and turning off the fluorine pump 36 when the outdoor temperature is higher than the second temperature.

In this embodiment, the containerized data center has a control module, which can detect the outdoor temperature and control operation of the liquid cooling system and the air cooling system. In practical applications, the liquid cooling system may be remained ON all the time for liquid cooling and heat dissipation of the main heat source of the to-be-cooled device set 51. For the air cooling system, the outdoor temperatures are different in different seasons. For example, winter has a minimum outdoor temperature, followed by spring and autumn, and summer has a maximum outdoor temperature. To better utilize outdoor temperature resources and reduce power consumption, the outdoor temperature may be detected, and functions of the air cooling system may be selectively enabled according to the outdoor temperature. For example, the first temperature may be preset to be 0° C., the second temperature is preset to be 15° C., the third temperature is preset to be 30° C., and the detected outdoor temperature is compared with the first temperature, the second temperature, and the third temperature. When the outdoor temperature is lower than the first temperature, the air cooling system only exchanges heat through the heat exchange core, the compressor or the fluorine pump system does not operate, and air is directly delivered to the data room for refrigeration. When the outdoor temperature is higher than the first temperature and is lower than the second temperature, the fluorine pump is turned on. After primary refrigeration by the heat exchange core, return air is refrigerated by the evaporator and then is delivered to the data room. As temperature of fresh air continues to rise, that is, when the outdoor temperature is higher than the second temperature, the fluorine pump can no longer meet the refrigeration demands. In this case, the compressor is turned on, and after the primary refrigeration by the heat exchange core, the return air is refrigerated by the evaporator and then is delivered to the data room.

As can be seen from the technical solutions provided in the present disclosure, an integrated refrigeration apparatus is connected to one side of the container body. The integrated refrigeration apparatus includes a body, a liquid cooling system, and an air cooling system. Both the liquid cooling system and the air cooling system are installed in the container body. That is, the two cooling systems are integrated into one body. Moreover, the liquid cooling system and the air cooling system share the same outdoor air inlet and the same outdoor air outlet, such that structures of the refrigeration apparatus can be further simplified, manufacturing costs can be lowered, and volumes occupied by the two cooling systems can be reduced. Thus, the two cooling systems are suitable to be arranged in the containerized data center.

Further, the to-be-cooled device set is installed inside the container body through the overhead seat, such that the liquid supply and return pipes are arranged inside the overhead seat. In this way, it is avoidable that pipelines are exposed outside, thereby avoiding adversely affecting daily maintenance and operation, and ensuring aesthetic degree of the containerized data center.

Further, in the air cooling system, the heat exchange core and a fluorine pump refrigeration cycle are integrated, such that a corresponding heat exchange mode may be adjusted according to external air temperature variations. In this way, heat exchange may be controlled by making the most of external air temperature to save electric power, and the heat dissipation effects of the to-be-cooled device set can be ensured.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A containerized data center at least comprising a container body and an integrated refrigeration apparatus; wherein
the container body is internally provided with a to-be-cooled device set dividing internal space of the container body into a cold channel and a hot channel;
the integrated refrigeration apparatus at least comprises a body, a liquid cooling system and an air cooling system, wherein the body is connected to one end of the container body, and the liquid cooling system and the air cooling system are installed in the body;
the body has an outdoor air inlet, an outdoor air outlet, an operating air inlet and an operating air outlet, wherein the operating air inlet is interconnected to the hot channel, and the operating air outlet is interconnected to the cold channel, such that after heat exchange through the air cooling system, hot air in the hot channel is discharged into the cold channel through the operating air outlet; and
the liquid cooling system at least comprises a dry cooler and a liquid supply and return pipe connected in series with the dry cooler, wherein the dry cooler is positioned between the outdoor air inlet and the outdoor air outlet, a plurality of liquid cooling cold plates are connected in series with the liquid supply and return pipe, the plurality of liquid cooling cold plates are connected in parallel with each other, and the plurality of liquid cooling cold plates respectively come into contact with a heat source of the to-be-cooled device set.

2. The containerized data center according to claim 1, wherein the to-be-cooled device set is installed inside the container body through an overhead seat; and
the liquid supply and return pipe is arranged inside the overhead seat.

3. The containerized data center according to claim 1, wherein the air cooling system at least comprises a heat exchange core; and
an internal circulation air inlet of the heat exchange core is interconnected to the operating air inlet, and an internal circulation air outlet of the heat exchange core is interconnected to the operating air outlet.

4. The containerized data center according to claim 3, wherein an air outlet channel is connected between the internal circulation air outlet and the operating air outlet;
the air cooling system further comprises a condenser, an evaporator, an expansion valve and a compressor, wherein the condenser, the evaporator, the expansion valve and the compressor are connected in series with each other to form a refrigeration cycle; and
the condenser is positioned between the outdoor air inlet and the outdoor air outlet, and the evaporator is installed in the air outlet channel.

5. The containerized data center according to claim 4, wherein the heat exchange core, the dry cooler, and the condenser are arranged side by side.

6. The containerized data center according to claim 5, wherein the air cooling system further comprises a fluorine pump and a one-way valve;
the fluorine pump is connected in series in the refrigeration cycle, and the fluorine pump is connected in parallel with the expansion valve; and
the one-way valve is connected in series in the refrigeration cycle, and the one-way valve is connected in parallel with the compressor.

7. The containerized data center according to claim 6, wherein a humidification and dehumidification section is installed in the air outlet channel, and the humidification and dehumidification section is positioned between the operating air outlet and the evaporator.

8. The containerized data center according to claim 7, wherein a filter section is installed in the air outlet channel to filter an airflow flowing through the air outlet channel.

9. The containerized data center according to claim 8, wherein a rainproof shutter and a filter mesh are installed at the outdoor air inlet.

10. A refrigeration method for a containerized data center, the refrigeration method being applied to the containerized data center provided with a liquid cooling system and an air cooling system, the refrigeration comprising:
starting the liquid cooling system and obtaining outdoor temperature;
determining magnitude of the outdoor temperature, of a first temperature, of a second temperature and of a third temperature, wherein the first temperature is less than the second temperature;
turning off a fluorine pump and a compressor in the air cooling system when the outdoor temperature is lower than the first temperature;
turning on the fluorine pump and turning off the compressor when the outdoor temperature is higher than the first temperature and is lower than the second temperature; and
turning on the compressor and turning off the fluorine pump when the outdoor temperature is higher than the second temperature.
